(19) United States
(12) Patent Application Publication
(10) Pub. No.: US 2025/0228054 A1
(43) Pub. Date: Jul. 10, 2025

(54) OPTOELECTRONIC DEVICE

(71) Applicant: EPISTAR CORPORATION, Hsinchu (TW)

(72) Inventors: Yu-Ling LIN, Hsinchu (TW); Yi-Hung LIN, Hsinchu (TW); Chao-Hsing CHEN, Hsinchu (TW); Chien-Ya HUNG, Hsinchu (TW)

(21) Appl. No.: 19/006,555

(22) Filed: Dec. 31, 2024

(30) Foreign Application Priority Data
Jan. 4, 2024 (TW) 113100406

(51) Int. Cl. H10H 29/80; H01L 25/075; H10H 29/85

(52) U.S. Cl. CPC H10H 29/8325; H01L 25/0753; H10H 29/857; H10H 29/942

(57) ABSTRACT

An optoelectronic device includes a semiconductor stack, including a first semiconductor layer, an active layer, and a second semiconductor layer; a contact electrode formed on the second semiconductor layer; an insulating reflective structure covering the contact electrode and including a plurality of insulating reflective structure openings to expose the contact electrode; a metal reflective structure covering the plurality of insulating reflective structure openings to electrically connect to the contact electrode; and an insulating structure including one or more first insulating structure openings to expose the first semiconductor layer and one or more second insulating structure openings to expose the metal reflective structure.

### REFERENCE TO RELATED APPLICATION

This application claims the right of priority based on TW application Ser. No. 11/310,0406, filed on Jan. 4, 2024, and the content of which is hereby incorporated by reference in its entirety.

### TECHNICAL FIELD

The application relates to an optoelectronic device, and more particularly, to a flip chip type optoelectronic device including a metal reflective structure and an insulating reflective structure.

### DESCRIPTION OF BACKGROUND ART

Light-Emitting Diode (LED) is a solid-state semiconductor optoelectronic device, which has the advantages of low power consumption, low heat generation, long working lifetime, shockproof, small volume, fast reaction speed, and good photoelectric property, such as stable emission wavelength. Therefore, the light-emitting diodes are widely used in the household appliances, the equipment indicators, and the optoelectronic products.

### SUMMARY OF THE APPLICATION

An optoelectronic device includes a semiconductor stack, including a first semiconductor layer, an active layer, and a second semiconductor layer; a contact electrode formed on the second semiconductor layer; an insulating reflective structure covering the contact electrode and including a plurality of insulating reflective structure openings to expose the contact electrode; a metal reflective structure covering the plurality of insulating reflective structure openings to electrically connect the contact electrode; an insulating structure including one or more first insulating structure openings to expose the first semiconductor layer and one or more second insulating structure openings to expose the metal reflective structure; a first extension electrode covering the semiconductor stack and the one or more first insulating structure openings to electrically connect the first semiconductor layer; and a second extension electrode covering the semiconductor stack and the one or more second insulating structure openings to electrically connect the metal reflective structure, wherein in a top view of the optoelectronic device, the one or more second insulating structure openings is respectively formed at any position within a polygon constituted by the plurality of insulating reflective structure openings.

### BRIEF DESCRIPTION OF THE DRAWINGS

FIG. 1 illustrates a top view of an optoelectronic device 1 in accordance with an embodiment of the present application;

FIG. 2 illustrates a top view of an optoelectronic device 2 in accordance with an embodiment of the present application;

FIG. 3 illustrates a top view of an optoelectronic device 3 in accordance with an embodiment of the present application;

FIG. 4 illustrates a top view of an optoelectronic device 4 in accordance with an embodiment of the present application;

FIG. 5 illustrates a top view of an optoelectronic device 5 in accordance with an embodiment of the present application;

FIG. 6 illustrates a top view of an optoelectronic device 6 in accordance with an embodiment of the present application;

FIG. 7 illustrates a cross-sectional view along the line L1-L1′ in FIG. 1, the line L2-L2′ in FIG. 2, the line L3-L3′ in FIG. 3, the line L4-L4′ in FIG. 4, the line L5-L5′ in FIG. 5 or the line L6-L6′ in FIG. 6 in accordance with an embodiment of the present application;

FIG. 8 illustrates a cross-sectional view along the line X1-X1′ in FIG. 1, the line X2-X2′ in FIG. 2, the line X3-X3′ in FIG. 3, the line X4-X4′ in FIG. 4, the line X5-X5′ in FIG. 5 or the line X6-X6′ in FIG. 6 in accordance with an embodiment of the present application;

FIG. 9 illustrates a cross-sectional view along the line Y1-Y1′ in FIG. 1, the line Y2-Y2′ in FIG. 2, the line Y3-Y3′ in FIG. 3, the line Y4-Y4′ in FIG. 4, the line Y5-Y5′ in FIG. 5 or the line Y6-Y6′ in FIG. 6 in accordance with an embodiment of the present application;

FIG. 10 illustrates a top view of the distribution of the insulating reflective structure openings of the optoelectronic device in accordance with an embodiment of the present application;

FIG. 11 illustrates a top view of the distribution of the insulating reflective structure openings of the optoelectronic device in accordance with an embodiment of the present application;

FIG. 12 illustrates a current distribution diagram of the optoelectronic device in accordance with an embodiment of the present application;

FIG. 13 illustrates a top view of the distribution of the insulating reflective structure openings in a comparative example of the present application;

FIG. 14 illustrates a current distribution diagram in the comparative example of the present application;

FIG. 15 illustrates a schematic diagram of a light-emitting apparatus 7 in accordance with an embodiment of the present application;

FIG. 16 illustrates a schematic diagram of a light-emitting apparatus 8 in accordance with an embodiment of the present application;

FIG. 17 illustrates a schematic diagram of a backlight module 9 in accordance with an embodiment of the present application;

FIG. 18 illustrates a schematic diagram of a display 100 in accordance with an embodiment of the present application;

FIG. 19 illustrates a schematic diagram of a light-emitting apparatus 1000 in accordance with an embodiment of the present application; and

FIG. 20 illustrates a schematic diagram of a light-emitting apparatus 10000 in accordance with an embodiment of the present application.

### DETAILED DESCRIPTION OF PREFERRED EMBODIMENTS

The embodiment of the application is illustrated in detail and is plotted in the drawings. The same or the similar part is illustrated in the drawings and the specification with the same number.

In accordance with an embodiment, the semiconductor device can be a semiconductor optoelectronic device such as a light-emitting diode (LED), a laser, a photo detector, a solar cell, or a power device. Taking the light-emitting device as an example of the semiconductor device, the main structure includes a buffer layer and a device structure formed on the buffer layer. Different device structures are provided depending on the device function of the semiconductor device. For example, the device structure of the light-emitting device includes a semiconductor light-emitting stack including a p-type semiconductor layer, an n-type semiconductor layer and an active region, and the active region includes a light-emitting layer, which can emit light with different wavelengths depending on the material composition thereof. The embodiments are provided below as relevant descriptions of the semiconductor devices. However, it can be understood that the semiconductor devices in these embodiments are only for illustration and are not intended to limit the present application.

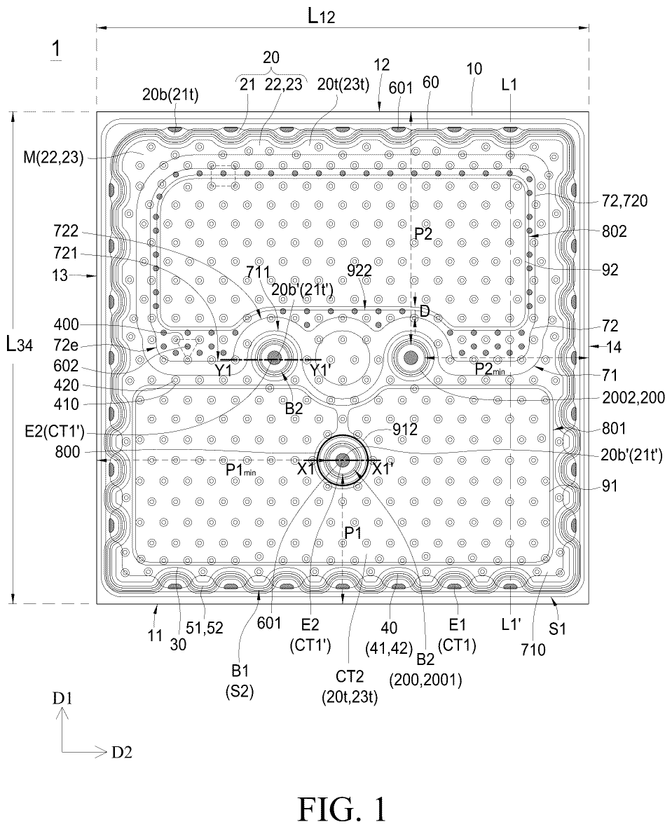

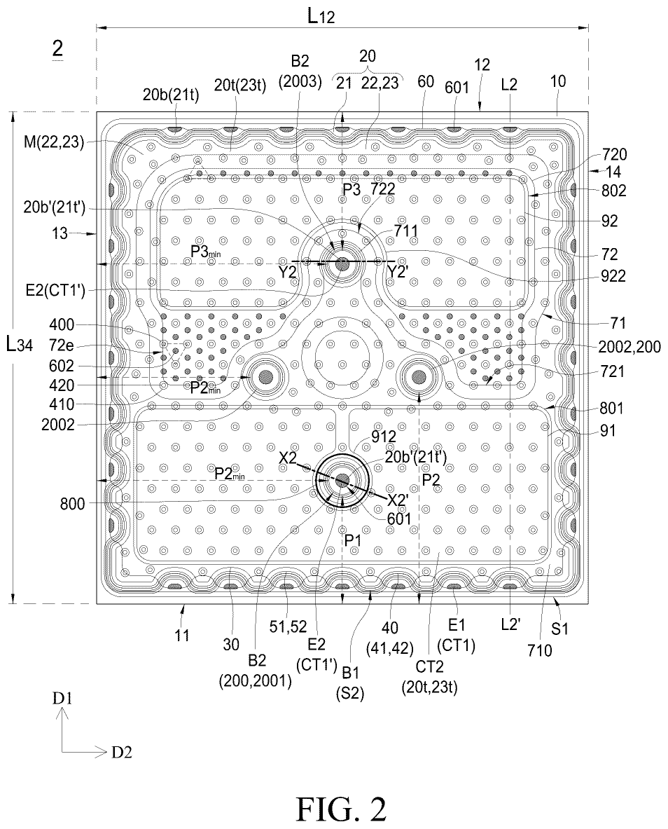

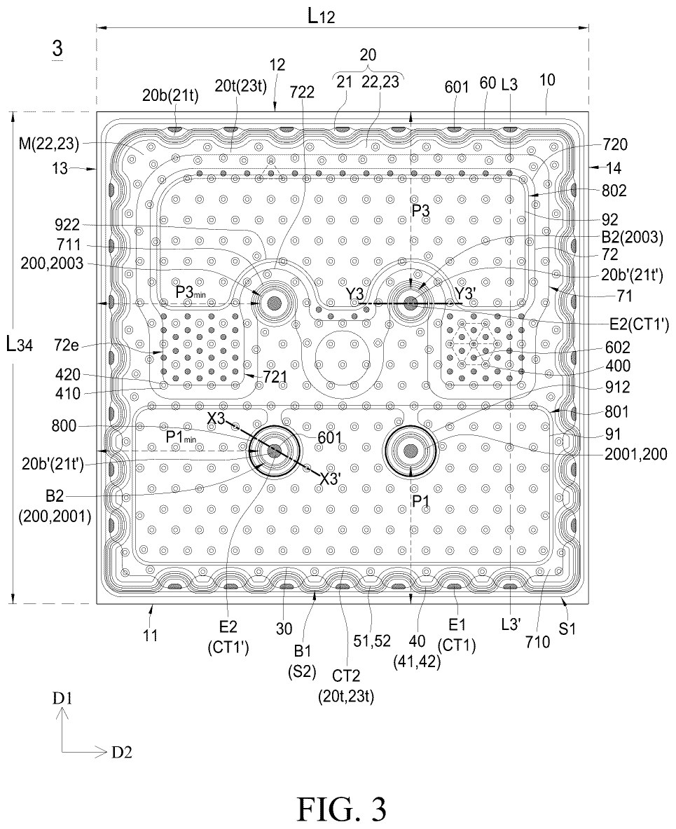

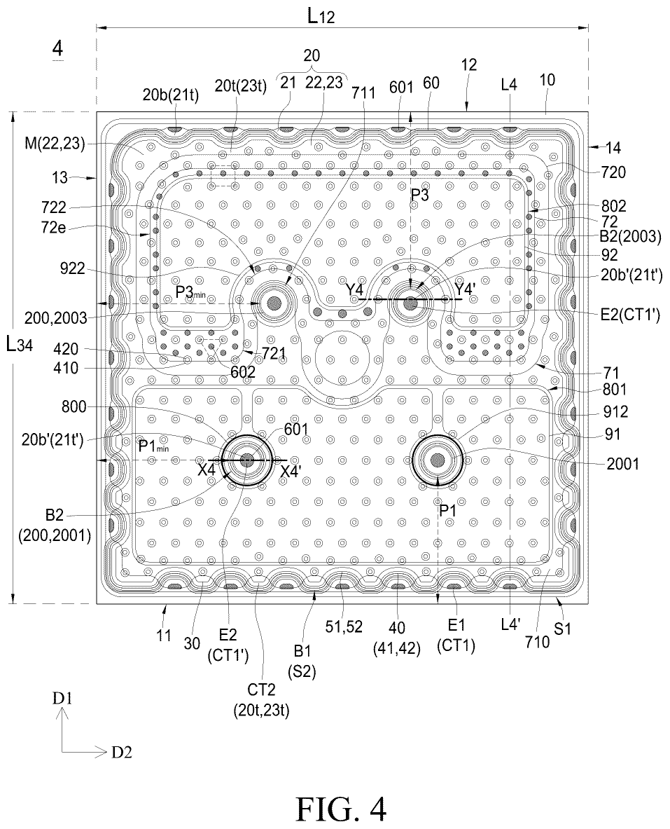

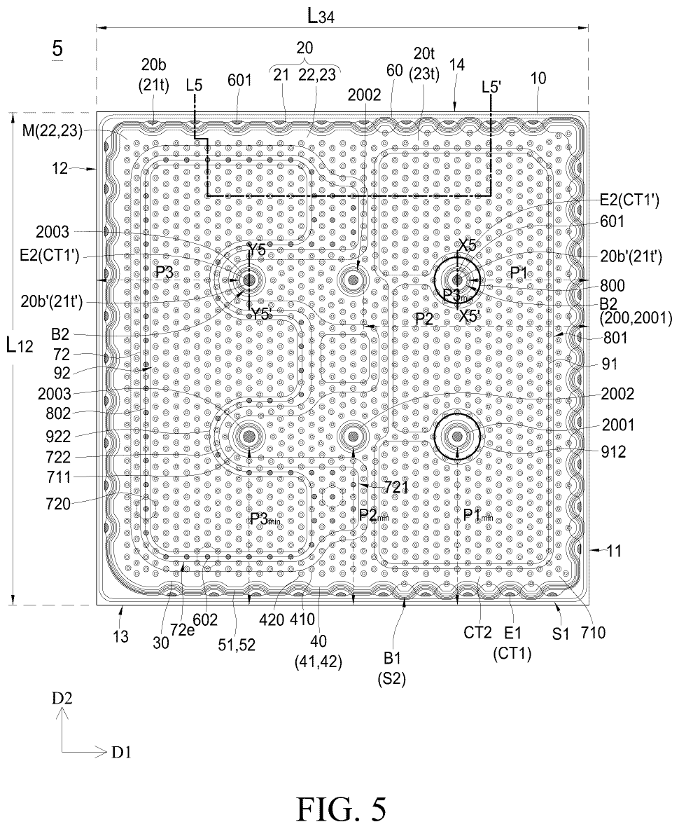

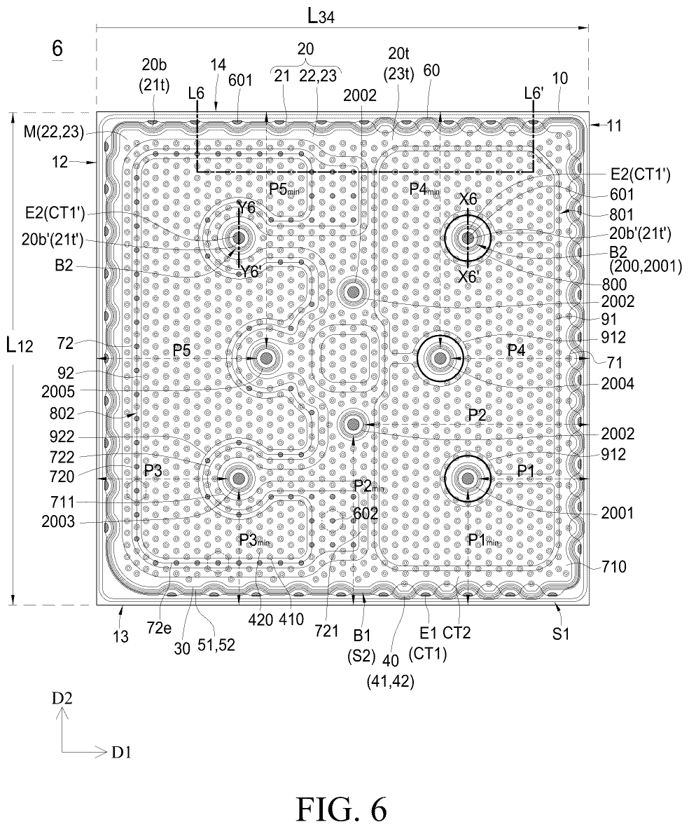

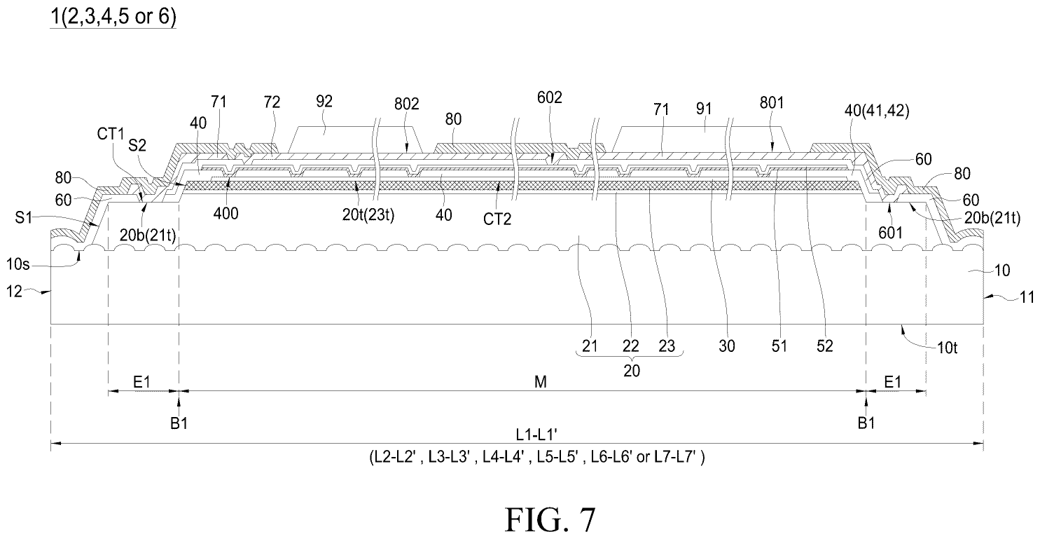

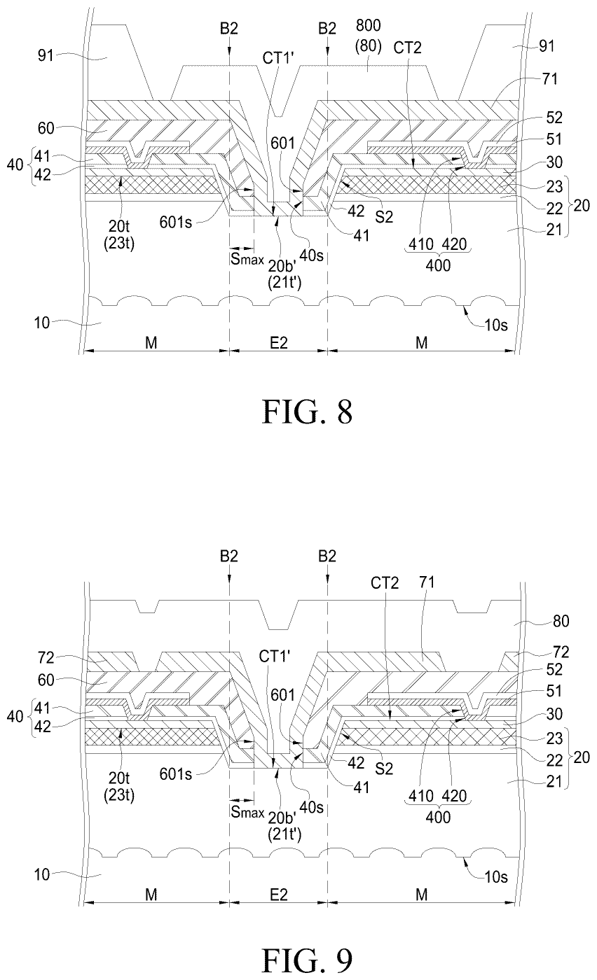

FIG. 1 illustrates a top view of an optoelectronic device 1 in accordance with an embodiment of the present application. FIGS. 2-6 illustrate the top views of the optoelectronic devices 2-6 varied from the optoelectronic device 1 illustrated in FIG. 1. FIG. 7 illustrates a cross-sectional view along the line L1-L1′ in FIG. 1, the line L2-L2′ in FIG. 2, the line L3-L3′ in FIG. 3, the line L4-L4′ in FIG. 4, and the line L5-L5′ in FIG. 5 or the line L6-L6′ in FIG. 6. FIG. 8 illustrates a cross-sectional view along the line X1-X1′ in FIG. 1, the line X2-X2′ in FIG. 2, the line X3-X3′ in FIG. 3, the line X4-X4′ in FIG. 4, the line X5-X5′ in FIG. 5 or the line X6-X6′ in FIG. 6. FIG. 9 illustrates a cross-sectional view along the line Y1-Y1′ of FIG. 1, the line Y2-Y2′ in FIG. 2, the line Y3-Y3′ in FIG. 3, the line Y4-Y4′ in FIG. 4, the line Y5-Y5′ in FIG. 5 or the line Y6-Y6′ in FIG. 6. The optoelectronic devices 1-6 of the application include electroluminescent devices, such as light-emitting diodes and laser diodes, or photoelectric devices, such as solar cells and light detectors.

Referring to FIGS. 1-6 and 7, the optoelectronic devices 1-6 each includes a substrate 10 including an upper surface 10s, a first semiconductor layer 21 formed on the upper surface 10s of the substrate 10 and including a first inclined surface S1 connected to the upper surface 10s of the substrate 10, and a semiconductor mesa M formed on the first semiconductor layer 21. The semiconductor mesa M includes an active layer 22 and a second semiconductor layer 23, and a second inclined surface S2 connected to a first surface 21t of the first semiconductor layer 21.

Referring to FIGS. 8-9, the optoelectronic devices 1-6 each includes a contact electrode 30 formed on the second semiconductor layer 23. An insulating reflective structure 40 is formed on the contact electrode 30 and includes a plurality of insulating reflective structure openings 400 formed on the second semiconductor layer 23. A connecting layer 51 covers the insulating reflective structure 40 and fills the plurality of insulating reflective structure openings 400 to contact the contact electrode 30, the second semiconductor layer 23, or both. A metal reflective structure 52 is formed on the connecting layer 51 and fills the plurality of insulating reflective structure openings 400.

Referring to FIGS. 7-9, each of the optoelectronic devices 1-6 includes an insulating structure 60 formed on the semiconductor mesa M, covering the connecting layer 51, the metal reflective structure 52 and the insulating reflective structure 40, and includes one or more first insulating structure openings 601 formed on the first semiconductor layer 21 and one or more second insulating structure openings 602 formed on the metal reflective structure 52.

Referring to FIG. 7, the optoelectronic devices 1-6 each includes a first extension electrode 71 covering the semiconductor mesa M to form an electrical connection with the first semiconductor layer 21 through the first insulating structure opening 601. A second extension electrode 72 covers the semiconductor mesa M and the second insulating structure opening 602 to form an electrical connection with the metal reflective structure 52 through the second insulating structure opening 602. The metal reflective structure 52 forms an electrical connection with the contact electrode 30, the second semiconductor layer 23, or both by covering the insulating reflective structure opening 400. A protective structure 80 covers the first extension electrode 71 and the second extension electrode 72, and includes a protective structure first opening 801 formed on the first extension electrode 71 and a protective structure second opening 802 formed on the second extension electrode 72. A first electrode pad 91 covers the protective structure first opening 801 to form an electrical connection with the first semiconductor layer 21 through the first extension electrode 71. A second electrode pad 92 covers the protective structure second opening 802 to form an electrical connection with the second semiconductor layer 23 through the second extension electrode 72.

The substrate 10 may be a growth substrate for the epitaxial growth of the semiconductor stack 20. In an embodiment, the semiconductor stack 20 includes the first semiconductor layer 21, the active layer 22 and the second semiconductor layer 23. The substrate 10 includes a gallium arsenide (GaAs) wafer for the epitaxial growth of aluminum gallium indium phosphide (AlGaInP), or a sapphire (Al₂O₃) wafer, a gallium nitride (GaN) wafer, a silicon carbide (SiC) wafer, or an aluminum nitride (AlN) wafer for the growth of gallium nitride (GaN), indium gallium nitride (InGaN), or aluminum gallium nitride (AlGaN).

In an embodiment of the present application, the optoelectronic device 1-6 may not have the substrate 10. For example, the substrate 10 can be a growth substrate for growing the semiconductor stack 20, and then the substrate 10 can be separated from the semiconductor stack 20 by laser lift off or chemical lift-off.

In an embodiment of the present application, the metal organic chemical vapor deposition (MOCVD), molecular beam epitaxy (MBE), hydride vapor phase epitaxy (HVPE), physical vapor deposition (PVD), or the ion plating method is provided to form the semiconductor stack 20 with optoelectrical characteristics on the substrate 10, such as a light-emitting stack. The physical vapor deposition method includes sputtering or evaporation.

The wavelength of the light emitted from or absorbed by the optoelectronic device 1 is adjusted by changing the physical and the chemical composition of one or more layers in the semiconductor stack 20. Taking the light-emitting device as an example, the semiconductor stack 20 includes the first semiconductor layer 21, the active layer 22 and the second semiconductor layer 23. The material of the semiconductor stack 20 includes III-V group semiconductor materials, such as AlₓIn_{y}Ga_{(1-x-y)}N or AlₓIn_{y}Ga_{(1-x-y)}P, where 0≤x, y≤1; (x+y)≤1. When the material of the semiconductor stack 20 includes AlInGaP series material, the red light having a wavelength between 610 nm and 650 nm can be emitted. When the material of the semiconductor stack 20 includes InGaN series material, the blue light having a wavelength between 400 nm and 490 nm or the green light having a wavelength between 530 nm and 570 nm can be emitted. When the material of the semiconductor stack 20 includes AlGaN series material or AlInGaN series material, the ultraviolet light having a wavelength between 250 nm and 400 nm can be emitted.

The first semiconductor layer 21 and the second semiconductor layer 23 can be cladding layers or confinement layers having different conductivity types, electrical properties, polarities, or doping elements for providing the electrons or the holes. For example, the first semiconductor layer 21 is an n-type semiconductor and the second semiconductor layer 23 is a p-type semiconductor. The active layer 22 is formed between the first semiconductor layer 21 and the second semiconductor layer 23. The electrons and the holes combine in the active layer 22 under a current driving to convert the electrical energy into the light energy to emit the light or convert the light energy into the electrical energy to absorb the light. The active layer 22 can be a single heterostructure (SH), a double heterostructure (DH), a double-side double heterostructure (DDH), or a multi-quantum well structure (MQW). The material of the active layer 22 can be an i-type, p-type or n-type semiconductor. The first semiconductor layer 21, the second semiconductor layer 22, or the active layer 23 can be a structure including a single layer or a plurality of sub-layers.

In an embodiment of the present application, the semiconductor stack 20 further includes a buffer layer (not shown) formed between the first semiconductor layer 21 and the substrate 10 which can release the stress caused by the lattice mismatch between the materials of the substrate 10 and the semiconductor stack 20, so the lattice dislocation and the lattice defect are reduced and the epitaxial quality of the semiconductor stack 20 is improved. The buffer layer includes a structure including a single layer or a plurality of sub-layers. In an embodiment, an aluminum nitride (AlN) layer formed by PVD method can be the buffer layer formed between the semiconductor stack 20 and the substrate 10 to improve the epitaxial quality of the semiconductor stack 20. In an embodiment, when the method for forming aluminum nitride (AlN) is PVD, the target can be made of aluminum nitride. In another embodiment, a target made of aluminum reacts with a nitrogen source to form the aluminum nitride.

As shown in FIGS. 7-9, the semiconductor stack 20 includes a first exposed area E1, a second exposed area E2, and a semiconductor mesa M surrounded by the first exposed area E1. In an embodiment, the second semiconductor layer 23, the active layer 22 and a portion of the first semiconductor layer 21 may be removed by etching to form the first exposed area E1 and the second exposed area E2. In other words, the first exposed area E1 exposes the first surface 21t of the first semiconductor layer 21 and the second exposed area E2 exposes the second surface 21t′ of the first semiconductor layer 21. In a top view of the optoelectronic device 1, as shown in FIG. 1, the first exposed area E1 is formed on at least one side of the semiconductor mesa M, and the second exposed area E2 is formed inside the semiconductor mesa M and is surrounded by the semiconductor mesa M. In FIG. 7, the mark “B1” represents the first boundary B1 between the first exposed area E1 and the semiconductor mesa M. In FIGS. 8-9, the mark “B2” represents the second boundary B2 between the second exposed area E2 and the semiconductor mesa M. The upper surface 20t of the semiconductor mesa M (the second upper surface 23t of the second semiconductor layer 23) may be higher than the upper surface 20b of the first exposed area E1 (the first surface 21t of the first semiconductor layer 21) and the upper surface 20b′ of the second exposed area E2 (the second surface 21t′ of the first semiconductor layer 21). In an embodiment, the semiconductor mesa M may narrow toward its top. Therefore, the side surface of the semiconductor mesa M may be an inclined surface, such as the second inclined surface S2 illustrated in FIGS. 2, 8 and 9.

In an embodiment, as shown in FIG. 7, a part of the upper surface 20b of the first exposed area E1 can be a first contact first area CT1. As shown in FIGS. 8 and 9, a part of the upper surface 20b′ of the second exposed area E2 can be a first contact second area CT1′. In an embodiment, at least a portion of the upper surface 20t of the semiconductor mesa M is defined as a second contact area CT2. The insulating structure 60 includes a plurality of first insulating structure openings 601 to expose the first contact first area CT1 and the first contact second area CT1′. The insulating reflective structure 40 includes a plurality of insulating reflective structure openings 400 formed on the second contact area CT2 to expose the contact electrode 30, the second semiconductor layer 23, or both. In an embodiment, the plurality of first contact second areas CT1′ includes a first total area A1, the plurality of first contact first areas CT1 includes a second total area A2, and a ratio (A1/A2) between 1˜2 can improve the current distribution of optoelectronic device 1-6. If the ratio (A1/A2) is less than 1, the brightness of the optoelectronic devices 1-6 will decrease; if the ratio (A1/A2) is greater than 2, the voltage (Vf) of the optoelectronic devices 1-6 will increase.

As shown in FIG. 1, the substrate 10 includes a first side 11, a second side 12, a third side 13 and a fourth side 14, and the semiconductor mesa M can be spaced apart from the first side 11 to the fourth side 14, and the first exposed areas E1 can be disposed between the semiconductor mesa M and any one side or any multiple sides of the first side 11 to the fourth side 14. For example, the first exposed area E1 can be disposed between the semiconductor mesa M and the first side 11 and between the semiconductor mesa M and the second side 12, or between the semiconductor mesa M and the third side 13 and between the semiconductor mesa M and the fourth side 14. The first side 11 and the second side 12 can be opposite to each other or parallel to each other, and the third side 13 and the fourth side 14 can be opposite to each other or parallel to each other. In an embodiment, the plurality of second exposed areas E2 having an elongated, rectangular, circular or oval shape can be spaced apart from each other to be arranged inside the semiconductor mesa M.

Referring to FIGS. 1-6, each of the optoelectronic devices 1-6 includes a plurality of through holes 200 penetrating through the second semiconductor layer 23 and the active layer 22 to form in the second exposed area E2 to expose the second surface 21t′ of the first semiconductor layer 21. The number of the through holes 200 includes multiple, the shapes include but are not limited to circles or polygons such as rectangles or hexagons, and the through holes 200 can be distributed at uniform or non-uniform intervals. In the embodiment, the shape of the through hole 200 is circular. After the current is injected into the optoelectronic devices 1-6, the first extension electrode 71 after being injected into the external current is electrically connected to the first semiconductor layer 21 in the through hole 200. The multiple through holes 200 are evenly distributed to improve the current spreading capability and the current distribution uniformity, and the contact area between the first extension electrode 71 and the first semiconductor layer 21 also increases, thereby reducing the voltage and improving the luminous efficiency of the optoelectronic devices 1-6.

The number and distribution of the through holes 200 can be designed according to the size of the optoelectronic device. The larger the size of the optoelectronic device is, the greater the number of the through holes 200 required.

As shown in FIG. 1, the distribution direction of the plurality of through holes 200 includes a first direction D1 extending from the first side 11 to the second side 12 of the substrate 10 and a second direction D2 extending from the third side 13 to the fourth side 14 of the substrate 10. The plurality of through holes 200 includes a first group of through holes 2001 and a second group of through holes 2002. The first group of through holes 2001 and the second group of through holes 2002 are sequentially provided in the first direction D1 extending from the first side 11 to the second side 12 of the substrate 10. The number of the first group of through holes 2001 or the second group of through holes 2002 can be one or more. In the first direction D1, a first distance P₁ between any one of the first group of through holes 2001 and the first side 11 is smaller than a second distance P₂ between any one of the second group of through holes 2002 and the first side 11, the second side 12, or both. The ratio P₁/L₃₄ of the first distance P₁ to the length L₃₄ of the third side 13 or the fourth side 14 of the optoelectronic device 1 is between 0.1˜0.5. The ratio P₂/L₃₄ of the second distance P₂ to the length L₃₄ of the third side 13 or the fourth side 14 of the optoelectronic device 1 is between 0.3˜0.7. In an embodiment, in the second direction D2, the minimum distance between any one of the first group of through holes 2001 and one of the third side 13 and the fourth side 14 is defined as the first minimum distance P1ₘᵢₙ, and the ratio P1ₘᵢₙ/L₁₂ of the first minimum distance P1ₘᵢₙ to the length L₁₂ of the first side 11 or the second side 12 is between 0.3˜0.7. The minimum distance between any one of the second group of through holes 2002 and one of the third side 13 and the fourth side 14 is defined as the second minimum distance P2ₘᵢₙ, and the ratio P2ₘᵢₙ/L₁₂ of the second minimum distance P2ₘᵢₙ to the length L₁₂ of the first side 11 or the second side 12 is between 0.1˜0.5. In another embodiment, the first minimum distance P1ₘᵢₙ is greater than the second minimum distance P2ₘᵢₙ.

As shown in FIG. 2, the plurality of through holes 200 includes the first group of through holes 2001, the second group of through holes 2002, and a third group of through holes 2003. The first group of through holes 2001, the second group of through holes 2002 and the third group of through holes 2003 are sequentially provided in the first direction D1 extending from the first side 11 to the second side 12 of the substrate 10. The number of the first group of through holes 2001, the second group of through holes 2002, or the third group of through holes 2003 can be one or more. In the first direction D1, the first distance P₁ between any one of the first group of through holes 2001 and the first side 11 is smaller than the second distance P₂ between any one of the second group of through holes 2002 and one of the first side 11 and the second side 12, and/or is smaller than a third distance P₃ between any one of the third group of through holes 2003 and the second side 12. The ratio P₁/L₃₄ of the first distance P₁ to the length L₃₄ of the third side 13 or the fourth side 14 of the optoelectronic device 2 is between 0.1˜0.5. The ratio P₂/L₃₄ of the second distance P₂ to the length L₃₄ of the third side 13 or the fourth side 14 of the optoelectronic device 2 is between 0.3˜0.7. The ratio P₃/L₃₄ of the third distance P₃ to the length L₃₄ of the third side 13 or the fourth side 14 of the optoelectronic device 2 is between 0.1˜0.5. In an embodiment, in the second direction D2, there is a first minimum distance P1ₘᵢₙ between one of the first group of through holes 2001 and one of the third side 13 and the fourth side 14, and the ratio P1ₘᵢₙ/L₁₂ of the first minimum distance P1ₘᵢₙ to the length L₁₂ of the first side 11 or the second side 12 is between 0.3˜0.7. There is a second minimum distance P2ₘᵢₙ between any one of the second group of through holes 2002 and one of the third side 13 and the fourth side 14, and the ratio P2ₘᵢₙ/L₁₂ of the second minimum distance P2ₘᵢₙ to the length L₁₂ of the first side 11 or the second side 12 is between 0.1˜0.5. There is a third minimum distance P3ₘᵢₙ between one of the third group of through holes 2003 and one of the third side 13 and the fourth side 14, and the ratio P3ₘᵢₙ/L₁₂ of the third minimum distance P3ₘᵢₙ to the length L₁₂ of the first side 11 or the second side 12 is between 0.3˜0.7. In another embodiment, the first minimum distance P1ₘᵢₙ and the third minimum distance P3ₘᵢₙ include the same or different distances, and the first minimum distance P1ₘᵢₙ and/or the third minimum distance P3ₘᵢₙ are greater than the second minimum distance P2ₘᵢₙ.

As shown in FIG. 3, the plurality of through holes 200 includes the first group of through holes 2001 and the third group of through holes 2003. The first group of through holes 2001 and the third group of through holes 2003 are sequentially provided in the first direction D1 extending from the first side 11 to the second side 12 of the substrate 10. The number of the first group of through holes 2001 or the third group of through holes 2003 can be one or more. In the first direction D1, the first distance P₁ between any one of the first group of through holes 2001 and the first side 11 is smaller than the third distance P₃ between any one of the third group of through holes 2003 and the second side 12. The ratio P₁/L₃₄ of the first distance P₁ to the length L₃₄ of the third side 13 or the fourth side 14 of the optoelectronic device 3 is between 0.1˜0.5. The ratio P₃/L₃₄ of the third distance P₃ to the length L₃₄ of the third side 13 or the fourth side 14 of the optoelectronic device 3 is between 0.1˜0.5. In an embodiment, in the second direction D2, there is a first minimum distance P1ₘᵢₙ between one of the first group of through holes 2001 and one of the third side 13 and the fourth side 14, and the ratio P1ₘᵢₙ/L₁₂ of the first minimum distance P1ₘᵢₙ to the length L₁₂ of the first side 11 or the second side 12 is between 0.1˜0.5. There is a third minimum distance P3ₘᵢₙ between one of the third group of through holes 2003 and one of the third side 13 and the fourth side 14, and the ratio P3ₘᵢₙ/L₁₂ of the third minimum distance P3ₘᵢₙ to the length L₁₂ of the first side 11 or the second side 12 is between 0.1˜0.5. In another embodiment, the first minimum distance P1ₘᵢₙ and the third minimum distance P3ₘᵢₙ include the same or different distances. For example, the first minimum distance P1ₘᵢₙ can be greater than the third minimum distance P3ₘᵢₙ.

As shown in FIG. 4, the plurality of through holes 200 includes the first group of through holes 2001 and the third group of through holes 2003. The first group of through holes 2001 and the third group of through holes 2003 are sequentially provided in the first direction D1 extending from the first side 11 to the second side 12 of the substrate 10. The number of the first group of through holes 2001 or the third group of through holes 2003 can be one or more. In the first direction D1, the first distance P1 between any one of the first group of through holes 2001 and the first side 11 is smaller than the third distance P₃ between any one of the third group of through holes 2003 and the second side 12. The ratio P₁/L₃₄ of the first distance P₁ to the length L₃₄ of the third side 13 or the fourth side 14 of the optoelectronic device 4 is between 0.1˜0.5. The ratio P₃/L₃₄ of the third distance P₃ to the length L₃₄ of the third side 13 or the fourth side 14 of the optoelectronic device 4 is between 0.1˜0.5. In an embodiment, in the second direction D2, there is a first minimum distance P1ₘᵢₙ between one of the first group of through holes 2001 and one of the third side 13 and the fourth side 14, and the ratio P1ₘᵢₙ/L₁₂ of the first minimum distance P1ₘᵢₙ to the length L₁₂ of the side 11 or the second side 12 is between 0.1˜0.5. There is a third minimum distance P₃ min between one of the third group of through holes 2003 and one of the third side 13 and the fourth side 14, and the ratio P3ₘᵢₙ/L₁₂ of the third minimum distance P3ₘᵢₙ to the length L₁₂ of the first side 11 or the second side 12 is between 0.1˜0.5. In another embodiment, the first minimum distance P1ₘᵢₙ and the third minimum distance P3ₘᵢₙ include the same or different distances. In the embodiment, the distance between the two through holes 200 in the first group of through holes 2001 is greater than the distance between the two through holes 200 in the third group of through holes 2003, and the first minimum distance P1ₘᵢₙ is smaller than the third minimum distance P3ₘᵢₙ.

As shown in FIG. 5, the plurality of through holes 200 includes the first group of through holes 2001, the second group of through holes 2002, and the third group of through holes 2003. The first group of through holes 2001, the second group of through holes 2002, and the third group of through holes 2003 are sequentially provided in the first direction D1 extending from the first side 11 to the second side 12 of the substrate 10. The number of the first group of through holes 2001, the second group of through holes 2002, or the third group of through holes 2003 can be one or more. In the first direction D1, the first distance P₁ between any one of the first group of through holes 2001 and the first side 11 is smaller than the second distance P₂ between any one of the second group of through holes 2002 and the first side 11, and/or is smaller than the third distance P₃ between any one of the third group of through holes 2003 and the second side 12. The ratio P₁/L₃₄ of the first distance P₁ to the length L₃₄ of the third side 13 or the fourth side 14 of the optoelectronic device 5 is between 0.1˜0.5. The ratio P₂/L₃₄ of the second distance P₂ to the length L₃₄ of the third side 13 or the fourth side 14 of the optoelectronic device 5 is between 0.3˜0.7. The ratio P₃/L₃₄ of the third distance P₃ to the length L₃₄ of the third side 13 or the fourth side 14 of the optoelectronic device 5 is between 0.1˜0.5. In an embodiment, in the second direction D2, there is the first minimum distance P1ₘᵢₙ between one of the first group of through holes 2001 and one of the third side 13 and the fourth side 14, and the ratio P1ₘᵢₙ/L₁₂ of the first minimum distance P1ₘᵢₙ to the length L₁₂ of the first side 11 or the second side 12 is between 0.1˜0.5. There is a second minimum distance P2ₘᵢₙ between any one of the second group of through holes 2002 and one of the third side 13 or the fourth side 14, and the ratio P2ₘᵢₙ/L₁₂ of the second minimum distance P2ₘᵢₙ to the length L₁₂ of the first side 11 or the second side 12 is between 0.1˜0.5. There is a third minimum distance P3ₘᵢₙ between one of the third group of through holes 2003 and one of the third side 13 or the fourth side 14, and the ratio P3ₘᵢₙ/L₁₂ of the third minimum distance P3ₘᵢₙ to the length L₁₂ of the first side 11 or the second side 12 is between 0.1˜0.5. In another embodiment, the first minimum distance P1ₘᵢₙ, the second minimum distance P2ₘᵢₙ and the third minimum distance P3ₘᵢₙ include the same distance.

As shown in FIG. 6, the plurality of through holes 200 includes the first group of through holes 2001, the second group of through holes 2002, and the third group of through holes 2003. The number of the first group of through holes 2001, the second group of through holes 2002, or the third group of through holes 2003 can be one or more. In the first direction D1, the first distance P₁ between any one of the first group of through holes 2001 and the first side 11 is smaller than the second distance P₂ between any one of the second group of through holes 2002 and the first side 11, and/or is smaller than the third distance P₃ between any one of the third group of through holes 2003 and the second side 12. The ratio P₁/L₃₄ of the first distance P₁ to the length L₃₄ of the third side 13 or the fourth side 14 of the optoelectronic device 6 is between 0.1˜0.5. The ratio P₂/L₃₄ of the second distance P₂ to the length L₃₄ of the third side 13 or the fourth side 14 of the optoelectronic device 6 is between 0.3˜0.7. The ratio P₃/L₃₄ of the third distance P₃ to the length L₃₄ of the third side 13 or the fourth side 14 of the optoelectronic device 6 is between 0.1˜0.5. In an embodiment, in the second direction D2, there is the first minimum distance P1ₘᵢₙ between one of the first group of through holes 2001 and the third side 13 or the fourth side 14, and the ratio P1ₘᵢₙ/L₁₂ of the first minimum distance P1ₘᵢₙ to the length L₁₂ of the side 11 or the second side 12 is between 0.1˜0.5. There is the second minimum distance P2ₘᵢₙ between any one of the second group of through holes 2002 and the third side 13 or the fourth side 14, and the ratio P2ₘᵢₙ/L₁₂ of the second minimum distance P2ₘᵢₙ to the length L₁₂ of the first side 11 or the second side 12 is between 0.3˜0.7. There is the third minimum distance P3ₘᵢₙ between one of the third group of through holes 2003 and one of the third side 13 or the fourth side 14, and the ratio P3ₘᵢₙ/L₁₂ of the third minimum distance P3ₘᵢₙ to the length L₁₂ of the first side 11 or the second side 12 is between 0.1˜0.5. In another embodiment, the first minimum distance P1ₘᵢₙ and the third minimum distance P3ₘᵢₙ include the same distance, and the first minimum distance P1ₘᵢₙ and/or the third minimum distance P3ₘᵢₙ are greater than the second minimum distance P2ₘᵢₙ. In the embodiment, the plurality of through holes 200 further includes a fourth group of through holes 2004 and a fifth group of through holes 2005, and the number of the fourth group of through holes 2004 and the fifth group of through holes 2005 can be one or more. The first group of through holes 2001, the fourth group of through holes 2004, the second group of through holes 2002, the fifth group of through holes 2005, and the third group of through holes 2003 are sequentially provided in the first direction D1 extending from the first side 11 to the second side 12 of the substrate 10. In the first direction D1, the first distance P₁ between any one of the first group of through holes 2001 and the first side 11 is smaller than a fourth distance P₄ between any one of the fourth group of through holes 2004 and the first side 11. The third distance P₃ between any one of the third group of through holes 2003 and the second side 12 is smaller than the fifth distance P₅ between any one of the fifth group of through holes 2005 and the second side 12. The ratio P₄/L₃₄ or P₅/L₃₄ of the fourth distance P₄, the fifth distance P₅ to the length L₃₄ of the third side 13 or the fourth side 14 of the optoelectronic device 6 is between 0.1˜0.5. In an embodiment, in the second direction D2, there is a fourth minimum distance P4ₘᵢₙ between one of the fourth group of through holes 2004 and one of the third side 13 and the fourth side 14, and there is a fifth minimum distance P5ₘᵢₙ between one of the fifth group of through holes 2005 and one of the third side 13 and the fourth side 14. The ratio P4ₘᵢₙ/L₁₂ and P5ₘᵢₙ/L₄₂ of the fourth minimum distance P4ₘᵢₙ and the fifth minimum distance P5ₘᵢₙ to the length L₁₂ of the first side 11 or the second side 12 is respectively between 0.1˜0.5. In another embodiment, the fourth minimum distance P4ₘᵢₙ and the fifth minimum distance P5ₘᵢₙ include the same distance.

Regarding the measurement method of the first distance P₁, the second distance P₂, the third distance P₃, the fourth distance P₄, the fifth distance P₅, the first minimum distance P1ₘᵢₙ, the second minimum distance P2ₘᵢₙ, the third minimum distance P3ₘᵢₙ, the fourth minimum distance P4ₘᵢₙ and the fifth minimum distance P5ₘᵢₙ can be as follows: (1) select the center of the through hole 200 for measurement; or (2) select the edge of the through hole 200 for measurement. The measurement method is not limited to this, as long as it can be measured at a consistent position of the through hole 200.

As shown in FIGS. 7-9, the contact electrode 30 can be directly disposed on the second semiconductor layer 23, and the area where the contact electrode 30 contacting with the second semiconductor layer 23 constitutes the second contact area CT2 and is electrically connected to the second semiconductor layer 23. The contact electrode 30 is used to spread the current injected from the outside and then inject the current into the second semiconductor layer 23 via the upper surface 20t of the semiconductor mesa M (the second upper surface 23t of the second semiconductor layer 23).

In an embodiment, the insulating reflective structure 40 includes a plurality of insulating reflective structure openings 400 disposed on the semiconductor mesa M. As shown in FIGS. 1-6, in the top view of the optoelectronic devices 1-6, the insulating reflective structure opening 400 includes a circle, a semicircle, an ellipse, a triangle, a rectangle, a polygon, an arc, or an annular shape. The plurality of insulating reflective structure openings 400 can be arranged on the semiconductor mesa M in a hexagonal arranged pattern, but it is not limited thereto. In another embodiment, the plurality of insulating reflective structure openings 400 can be arranged in various patterns. For example, a rectangular pattern. As shown in FIG. 7, the insulating reflective structure 40 is formed on the contact electrode 30, covers the second inclined surface S2 of the semiconductor mesa M, and covers a part of the first semiconductor layer 21 and a part of the second semiconductor layer 23. For example, the insulating reflective structure 40 covers a portion of the first surface 21t of the first semiconductor layer 21 and a portion of the second upper surface 23t of the second semiconductor layer 23.

In an embodiment of the application, as shown in FIGS. 7-9, the insulating reflective structure 40 includes an insulating mirror 41, an insulating layer 42, or both. The insulative reflective structure opening 400 includes a first insulating reflective structure opening 410 passing through the insulating mirror 41. As shown in FIGS. 8-9, the insulating mirror 41 of the insulating reflective structure 40 covers the second inclined surface S2 of the semiconductor mesa M to reflect the light from the active layer 22 and increase the light extraction efficiency of the optoelectronic devices 1-6.

In an embodiment of the application, as shown in FIGS. 8-9, the insulating layer 42 of the insulating reflective structure 40 is formed between the contact electrode 30 and the insulating mirror 41. The insulating reflective structure opening 400 includes a second insulating reflective structure opening 420 passing through the insulating layer 42. As shown in FIGS. 1-6, in the top view of the optoelectronic devices 1-6, the first insulating reflective structure opening 410 and the second insulating reflective structure opening 420 form a concentric circle pattern.

As shown in FIGS. 8-9, the connecting layer 51 covers the insulating reflective structure 40 and fills the first insulating reflective structure opening 410 and the second insulating reflective structure opening 420 to contact the contact electrode 30, wherein the connecting layer 51 includes titanium (Ti), titanium oxide (TiOₓ), titanium nitride (TiNₓ), aluminum oxide (Al₂O₃), indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1). The contact electrode 30 includes indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1). In an embodiment of the application, the connecting layer 51 includes a thickness smaller than the thickness of the contact electrode 30. For example, the connecting layer 51 includes a thickness between 10 Å and 60 Å, and the contact electrode 30 includes a thickness between 100 Å and 400 Å. In an embodiment of the application, the contact electrode 30 and the connecting layer 51 include a same material. For example, the contact electrode 30 and the connecting layer 51 include indium tin oxide (ITO). In an embodiment of the application, the contact electrode 30 and the connecting layer 51 include different materials. For example, the contact electrode 30 includes indium tin oxide (ITO), and the connecting layer 51 includes titanium (Ti).

The metal reflective structure 52 fills the insulating reflective structure opening 400 of the insulating reflective structure 40 through the connecting layer 51, wherein the connecting layer 51 can improve the adhesion between the insulating reflective structure 40 and the metal reflective structure 52. In the side view of the optoelectronic devices 1-6, in an embodiment, the metal reflective structure 52 can be disposed on the connecting layer 51 and conform to the shape of the connecting layer 51. For example, the metal reflective structure 52 and the connecting layer 51 may completely overlap or partially overlap each other.

In an embodiment, the metal reflective structure 52 includes silver (Ag), chromium (Cr), nickel (Ni), titanium (Ti), aluminum (Al), rhodium (Rh), ruthenium (Ru) or the above combination of materials.

In an embodiment, the optoelectronic devices 1-6 each includes a barrier layer (not shown) disposed on the metal reflective structure 52. The barrier layer has a multi-layer structure, for example, the multi-layer structure having the alternately stacked Ti layers and Ni layers.

The insulating reflective structure 40, the connecting layer 51 and the metal reflective structure 52 can be configured as an omnidirectional reflector (Omni-Directional Reflector, ODR). The omnidirectional reflector can increase the reflectivity of the light emitted from the active layer 22, thereby improving the light extraction efficiency of the optoelectronic devices 1-6.

In an embodiment, the insulating layer 42 of the insulating reflective structure 40 serves as an insulating film and has a single-layer structure, including an oxide or a nitride, such as selected from at least one oxide or nitride from the group consisting of silicon (Si), titanium (Ti), and zirconium (Zr), niobium (Nb), tantalum (Ta), aluminum (Al), etc. In another embodiment, the insulating layer 42 may also be a multi-layer structure, such as a stack composed of any two or more of the above-mentioned oxides or nitrides, such as a multi-layer structure composed of SiO₂, TiO₂ and Al₂O₃.

In an embodiment, the insulating mirror 41 can be formed of a material with a refractive index lower than that of the second semiconductor layer 23. The material of the insulating mirror 41 includes SiO₂, SiN, SiOₓN_{y}, TiO₂, Si₃N₄, Al₂O₃,TiN, AlN, ZrO₂, TiAlN, TiSiN, HfO, TaO₂, Nb₂O₅, or MgF₂. In an embodiment, the insulating mirror 41 has a multi-layer film structure in which the insulating sub-layers with different refractive indexes are alternately stacked, such as a Distributed Bragg Reflector (DBR). The Distributed Bragg Reflector structure is formed by alternately stacking a plurality of first sub-layers having a first refractive index and a plurality of second sub-layers having a second refractive index, and the first refractive index is smaller than the second refractive index. For example, SiO₂/TiO₂ or SiO₂/Nb₂O₅ can be stacked.

In an embodiment of the application, when the insulating mirror 41 includes a Distributed Bragg Reflector structure stacked with SiO₂/TiO₂ or SiO₂/Nb₂O₅, the insulating layer 42 has a thickness greater than that of each of the sub-layers of the insulating mirrors 41. The thickness of the insulating layer 42 is less than the total thickness of the sub-layers of the insulating mirror 41. In an embodiment of the application, the thickness of the insulating layer 42 is between 3000 Å and 7000 Å.

The bottommost layer or the topmost layer of the insulating mirror 41 can be at least one oxide or nitride selected from the group consisting of silicon (Si), titanium (Ti), zirconium (Zr), niobium (Nb), tantalum (Ta), and aluminum (Al). In an embodiment, the bottommost layer and/or the topmost layer of the insulating mirror 41 includes a material and/or a thickness different from the middle layer and/or a forming method different from the middle layer.

In an embodiment, the insulating layer 42 may include a same material as the plurality of first sub-layers of the insulating mirror 41. For example, when the insulating mirror 41 is formed of a Distributed Bragg Reflector including SiO₂/TiO₂ or SiO₂/Nb₂O₅, the insulating layer 42 can be formed of SiO₂. Although the insulating layer 42 is formed of a same material as at least a part of the insulating mirror 41, it is not required to have as high film quality as the insulating film of DBR, and therefore the insulating mirror 41 and the insulating layer 42 can be formed by different processes. The interface between the insulating layer 42 and the insulating mirror 41 can be distinguished visually (eg, SEM photos or TEM photos). In an embodiment, the total thickness of the plurality of first sub-layers of the insulating mirror 41 is less than the total thickness of the insulating layer 42.

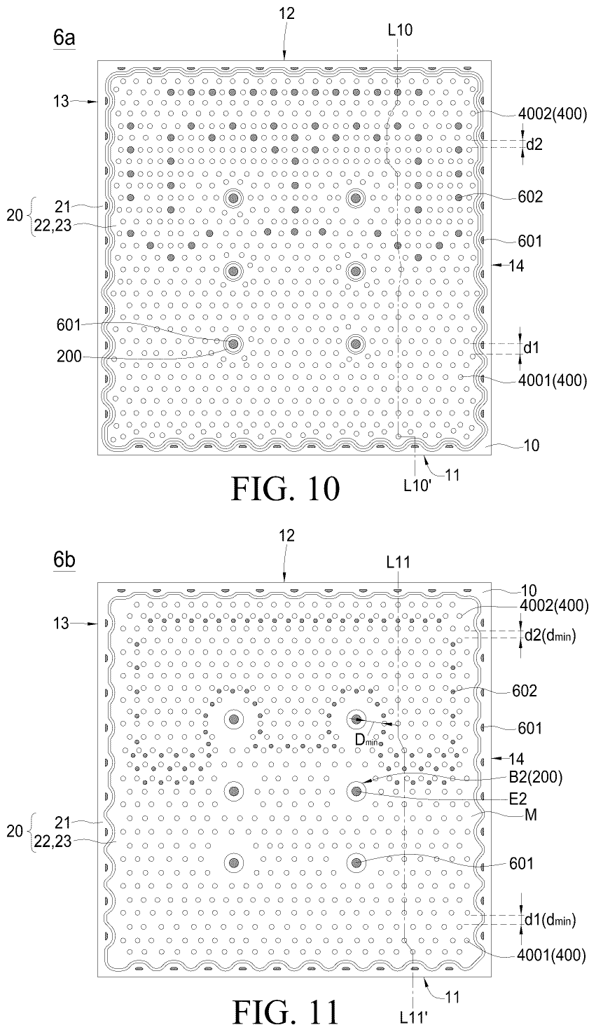

In the embodiments of the present application, among the plurality of insulating reflective structure openings 400, there is a minimum distance dₘᵢₙ between any two adjacent openings. Taking the embodiments of the present application in FIGS. 10-11 as examples, which disclose the top views of the distribution of the insulating reflective structures openings 400 in the optoelectronic devices 6a-6b. Similar to the embodiments illustrated in FIGS. 1-6, the optoelectronic devices 6a-6b disclosed in FIGS. 10-11 are also similar to the structures included in the optoelectronic devices 1-6. For ease of explanation, FIGS. 10-11 omit the first extension electrode 71, the second extension electrode 72, the protective structure 80, the first electrode pad 91 and the second electrode pad 92, and only disclose the substrate 10, the semiconductor stack layer 20, the through hole 200, the plurality of insulating reflective structure openings 400, the first insulating structure opening 601, and the second insulating structure opening 602. The cross-sectional views of the line L10-L10′ in FIG. 10 and the line L11-L11′ in FIG. 11 can be referred to FIG. 7. The plurality of insulating reflective structure openings 400 includes a first group of openings 4001 formed on one side of the optoelectronic device and a second group of openings 4002 formed on the other side of the optoelectronic device to improve the current spreading uniformity of the optoelectronic device, wherein the minimum distance dₘᵢₙ between adjacent insulating reflective structure openings of the first group of openings 4001 and the second group of openings 4002 is not equal. Specifically, a first minimum distance d1 between any two adjacent openings of the first group of openings 4001 is greater than a second minimum distance d2 between any two adjacent openings of the second group of openings 4004. In other words, any two adjacent openings of the first group of openings 4001 are separated by the first minimum distance d1, any two adjacent openings of the second group of the openings 4004 are separated by the second minimum distance d2, and the first minimum distance d1 is greater than the second minimum distance d2. In an embodiment, the first group of openings 4001 of the plurality of insulating reflective structure openings 400 is formed under the first electrode pad 91 (not shown), and the second group of openings 4002 of the plurality of insulating reflective structure openings 400 is formed under the second electrode pad 92 (not shown). In an embodiment, the first minimum distance d1 between any two adjacent openings can be equal to or unequal to each other in the first group of openings 4001. In the second group of openings 4004, the second minimum distance d2 between any two adjacent openings can be equal to or unequal to each other. In the cross-sectional view (not shown) or the top view of the optoelectronic device, the measurement method of the first minimum distance d1 and the second minimum distance d2 can be as follows: (1) select the center of the insulating reflective structure opening 400 for measurement; (2) select the edge position of the insulating reflective structure opening 400 for measurement. The measurement method is not limited to this, as long as it can be measured at a consistent position.

In order to improve the current spreading uniformity of the optoelectronic device, in an embodiment, as shown in FIG. 11, the plurality of insulating reflective structure openings 400 is arranged in a ring along the second boundary B2 between the second exposed area E2 and the semiconductor mesa M. The plurality of insulating reflective structure openings 400 surrounds the through hole 200 with a minimum distance Dₘᵢₙ, the plurality of insulating reflective structure openings 400 surrounding the through hole 200 is spaced apart from each other by a minimum distance dₘᵢₙ, and the minimum distance Dₘᵢₙ between the insulating reflective structure opening 400 and the through hole 200 is greater than the minimum distance dₘᵢₙ between the plurality of insulative reflective structure openings 400.

In an embodiment (not shown), the first minimum distance d1 between the first group of openings 4001 illustrated in FIG. 10 and the second minimum distance d2 between the second group of openings 4002 can be applied to the optoelectronic device illustrated in FIG. 11. The minimum distance Dₘᵢₙ between the insulating reflective structure opening 400 and the through hole 200 can be greater than the first minimum distance d1 between the first group of openings 4001 and/or greater than the second minimum distance d2 between the second group of openings 4002.

In an embodiment, as shown in FIGS. 10 and 11, the plurality of insulating reflective structure openings 400 can be equally spaced or non-equally spaced to surround the second boundary B2 of the second exposed area E2.

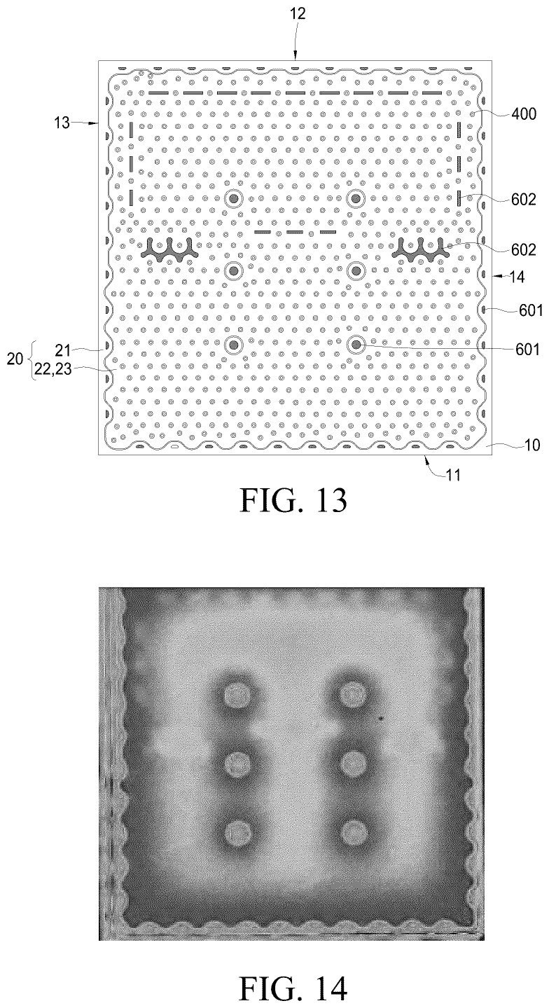

FIG. 13 illustrates a top view of the distribution of the insulating reflective structure openings 400 in a comparative example of the present application. As shown in FIG. 13, the second insulating structure opening 602 includes an irregular shape or a rectangle shape, and includes a top view area, a width, or a length larger than the top view area, the width, or the length of the insulating reflective structure opening 400. In order to accommodate the second insulating structure opening 602 and prevent the second insulating structure opening 602 from overlapping the insulating reflective structure opening 400, the insulating reflective structure openings 400 close to the second insulating structure opening 602 can be arranged in an irregular pattern, The insulating reflective structure openings 400 in other areas are arranged in a hexagonal grid pattern.

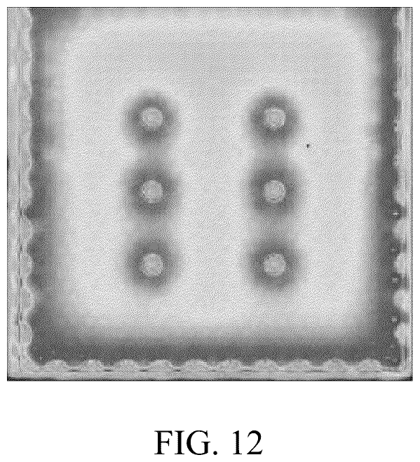

FIG. 12 illustrates the current distribution diagram of the optoelectronic devices 1-6 or 6a-6b in accordance with an embodiment of the present application. FIG. 14 illustrates the current distribution diagram of the comparative example of the present application. The dark area in FIG. 12 is smaller than the dark area in FIG. 14. Comparing with the comparative example, the optoelectronic devices 1-6 or 6a-6b provide a more uniform current distribution by arranging the second insulating structure opening at any position within the polygon constituted by the plurality of insulating reflective structure openings.

As shown in FIGS. 8-9, the insulating structure 60 can expose a side wall 40s of the insulating reflective structure 40. In another embodiment (not shown), the insulating structure 60 may cover the sidewall 40s of the insulating reflective structure 40. In another embodiment, there is a minimum distance Sₘₐₓ greater than 10 microns (μm) between a first sidewall 601s of the first insulating structure opening 601 and the second inclined surface S2 of the semiconductor mesa M to ensure that the insulating structure 60 including a thickness capable of covering the insulating reflective structure 40 to avoid damaging the insulating reflective structure 40 and reducing the reflectivity of the insulating reflective structure 40 when the insulating structure 60 is etched and removed to form the first insulating structure opening 601. The first extension electrode 71 connects to the first semiconductor layer 21 exposed in the first exposed area E1 and the second exposed area E2 through the first insulating structure opening 601.

As shown in FIGS. 7-9, the insulating structure 60 continuously covers all exposed surfaces of the metal reflective structure 52 and the connecting layer 51 to protect the metal reflective structure 52, such as the upper and side surfaces of the metal reflective structure 52 and the connecting layer 51. The metal reflective structure 52 and the connecting layer 51 can be encapsulated between the insulating structure 60 and the insulating reflective structure 40. In an embodiment of the application, the reflectivity of the metal reflective structure 52 can be prevented from being degraded due to subsequent processes by forming the insulating structure 60, and the metal migration in the metal reflective structure 52 can be suppressed.

In an embodiment of the application, in order to increase the light extraction efficiency of the optoelectronic devices 1-6, the insulating structure 60 includes a first Distributed Bragg Reflector (DBR) structure, which is composed of by alternately stacking a plurality of non-metal oxide or nitride layers and a plurality of metal oxide or nitride layers. The materials of the non-metal oxide or nitride layer include SiO₂, SiN, SiOₓN_{y}, and Si₃N₄. The material of the metal oxide or nitride layer includes TiO₂, Si₃N₄, Al₂O₃,TiN, AlN, ZrO₂, TiAlN, TiSiN, HfO, TaO₂, or Nb₂O₅. For example, SiO₂/TiO₂ or SiO₂/Nb₂O₅ can be stacked. In order to improve the adhesion between the insulating structure 60 and the first extension electrode 71, the metal reflective structure 52, the metal reflective structure 52 includes a metal other than silver (Ag), such as platinum (Pt), to connect the non-metal oxide or nitride layer of the insulating structure 60, such as SiO₂, and the insulating structure 60 is connected to the first extension electrode 71 through the metal oxide or nitride layer, such as TiO₂ or Nb₂O₅.

In an embodiment, as shown in FIGS. 1-6, the second insulating structure opening 602 and the plurality of insulating reflective structure openings 400 are disposed in a staggered manner, that is, the second insulating structure opening 602 does not overlap with the plurality of insulating reflective structure openings 400. In order to maintain a pattern in which the plurality of insulating reflective structure openings 400 is arranged at equal intervals, one or more second insulating structure openings 602 are respectively formed on any position within the polygon constituted by the plurality of insulating reflective structure openings 400 in the top view of the optoelectronic device. In an embodiment, the polygon constituted by the plurality of insulating reflective structure openings 400 includes a triangular, rectangular, pentagonal, or hexagonal arrangement. In an embodiment, the rectangle includes a square, a rectangle, a trapezoid or any quadrilateral. In an embodiment, the triangle can be an equilateral triangle or an isosceles triangle. In an embodiment, the position of the second insulating structure opening 602 can be located at an incenter, a circumcenter, an orthocenter, or a centroid of the triangle.

In an embodiment, there is only one second insulating structure opening 602 formed inside any polygon constituted by the plurality of insulating reflective structure openings 400.

In an embodiment, as shown in FIG. 1 or FIG. 4, the second insulating structure opening 602 can be formed within the rectangle formed by the plurality of insulating reflective structure openings 400. In another embodiment, as shown in FIG. 1, FIG. 2 or FIG. 4, the second insulating structure opening 602 can be formed within the triangle formed by the plurality of insulating reflective structure openings 400.

In an embodiment, as shown in FIG. 1, one of the two adjacent second insulating structure openings 602 is formed at any position within the rectangle formed by the plurality of insulating reflective structure openings 400. The other one of the two adjacent second insulating structure openings 602 is formed at any position within the triangle formed by the plurality of insulating reflective structure openings 400.

In an embodiment, as shown in FIG. 5 or FIG. 6, there is only one second insulating structure opening 602 provided in the hexagon formed by the plurality of insulating reflective structure openings 400. In an embodiment, as shown in FIG. 3, six second insulating structure openings 602 are formed inside the hexagon constituted by the plurality of insulating reflective structure openings 400.

In the embodiment, the second insulating structure opening 602 includes a width nor greater than the width of the insulating reflective structure opening 400. In another embodiment, each of the one or more second insulating structure openings 602 includes a width greater than a width of each of the plurality of insulating reflective structure openings 400.

As shown in FIGS. 1-6, one or more second insulating structure openings 602 are located in an area outside the projected area of the second electrode pad 92 and is covered by the second extension electrode 72. As shown in FIGS. 1, 4, 5 and 6, the plurality of second insulating structure openings 602 is arranged along the periphery of the second electrode pad 92. A portion of the plurality of second insulating structure openings 602 overlaps with the edge of the protective structure second opening 802 and can be disposed at equal or non-equal intervals around the second electrode pad 92 or on one side of the second electrode pad 92. As shown in FIGS. 2-3, the plurality of second insulating structure openings 602 can be formed only on two opposite sides of the second electrode pad 92. In another embodiment, the pattern of the second insulating structure opening 602 shown in FIGS. 1-6 can be illustrated as a rectangle, a triangle, or a regular or irregular polygon in addition to a circle.

In an embodiment, as shown in FIGS. 1-3 and 5-6, the second insulating structure openings 602 include the same width or diameter. In an embodiment, as shown in FIG. 4, the second insulating structure openings 602 include different widths or diameters.

As shown in FIGS. 7-9, the first extension electrode 71 can be disposed on the insulating structure 60 and extends through the first insulating structure opening 601 to the first contact first area CT1 and the first contact second area CT1′ to contact with the first semiconductor layer 21 and electrically connect the first semiconductor layer 21. In an embodiment, in order to improve the contact resistance between the first extension electrode 71 and the first semiconductor layer 21, a conductive contact layer (not shown) can be provided between the first extension electrode 71 and the first semiconductor layer 21. The conductive contact layer includes indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum-doped zinc oxide (AZO), gallium-doped zinc oxide (GZO), or zinc-magnesium oxide (Zn₍₁₋ₓ₎MgₓO, 0≤x≤1) and other conductive metal oxides. In an embodiment, a metal contact layer (not shown) can be disposed on the upper surface 20b of the first exposed area E1 and/or the upper surface 20b′ of the second exposed area E2. A part of the upper surface of the metal contact layer can be the first contact first area CT1 and/or the first contact second area CT1′.

The second extension electrode 72 can be disposed on the insulating structure 60 and extends to the metal reflective structure 52 through the second insulating structure opening 602 to electrically connect the second semiconductor layer 23.

Referring to FIGS. 1-6 and 8, the first extension electrode 71 includes a first electrode connection portion 710 close to the first side 11 of the substrate 10 and one or more first extension electrode protrusions 711 extending toward the second side 12 of the substrate 10. The second extension electrode 72 includes a second electrode connecting portion 720 close to the second side 12 of the substrate 10 and one or more second extension electrode recesses 722 extending toward the second side 12 of the substrate 10. In the top view, the second insulating structure opening 602 is located within the projected area of the second extension electrode 72, so that the second extension electrode 72 can fill the second insulating structure opening 602 to electrically connect the second semiconductor layer 23, and the edge 72e of the second extension electrode 72 covers the insulating reflective structure opening 400.

The arrangement of the first extension electrode 71 and the second extension electrode 72 are staggered, and the width of the first extension electrode protrusion 711 is smaller than the width of the second extension electrode recess 722, thereby allowing the second extension electrode 72 to avoid the position of the through hole 200 which also makes the upper surfaces of the second extension electrode 72 and the second electrode pad 92 to be a more planarized surface or a flatter surface.

Comparing with the second extension electrode recess 722, the second extension electrode 72 includes a second extension electrode protrusion 721. Specifically, in the top view of the optoelectronic devices 1-6, based on an auxiliary line drawn along an edge of the first extension electrode protrusion 711 closest to the second side 12 and parallel to the second direction, the second extension electrode recess 722 and the second extension electrode protrusion 721 are formed on opposite sides of the auxiliary line. In an embodiment in which the second insulating structure opening 602 is formed within a polygon constituted by the plurality of insulating reflective structure openings 400, one or more second insulating structure openings 602 is formed within the polygon constituted by the insulating reflective structure opening 400 under the second extension electrode protrusion 721.

In an embodiment, the first extension electrode 71 and the second extension electrode 72 can be disposed on the insulating structure 60, include different materials, and are spaced apart from each other. For example, the first extension electrode 71 and the second extension electrode 72 can be formed of a material including at least one of the following: aluminum (Al), gold (Au), tungsten (W), platinum (Pt), iridium (Ir), silver (Ag), copper (Cu), nickel (Ni), titanium (Ti), chromium (Cr) and the alloy of the above materials.

The protective structure 80 includes a protective structure first opening 801 formed on the first extension electrode 71 and a protective structure second opening 802 formed on the second extension electrode 72. The protective structure first opening 801 may expose the first extension electrode 71, and the protective structure second opening 802 may expose the second extension electrode 71. Referring to FIGS. 1-6 and 8, the optoelectronic devices 1-6 each includes one or a plurality of protective mesas 800 respectively covering one or the plurality of through holes 200. One or the plurality of protective mesas 800 is located outside the projected area of the first electrode pad 91, avoid the position of the through hole 200, which makes the upper surface of the first electrode pad 91 to be flatter.

Referring to FIGS. 1-6, in the top view, the projections of the first electrode pad 91 and the second electrode pad 92 do not overlap with the projection of the through hole 200, thereby making the surfaces of the optoelectronic devices 1-6 flatter, which is beneficial to increase the bonding area between the packaging substrate and the first electrode pad 91 and the second electrode pad 92 during the subsequent packaging process. Referring to FIGS. 8-9, the first insulating structure openings 601 are located in areas outside the projected area of the first electrode pad 91 and is covered by the first extension electrode 71.

Referring to FIGS. 1-6, the first group of through holes 2001 of the plurality of through holes 200 is surrounded by the first electrode pad 91, and/or the second group of through holes 2002 is surrounded by the second electrode pad 92. The first electrode pad 91 includes one or the plurality of first electrode pad recesses 912 to accommodate the first group of through holes 2001, and/or the second electrode pad 92 includes one or the plurality of second electrode pad recesses 922 to accommodate the second group of through holes 2002. In an embodiment, as shown in FIGS. 1-2, the first electrode pad recess 912 extends toward the interior of the first electrode pad 91. In an embodiment, as shown in FIGS. 3-5, the plurality of first electrode pad recesses 912 is formed on the same side of the first electrode pad 91 and extends toward the interior of the first electrode pad 91. In another embodiment, as shown in FIG. 6, the plurality of first electrode pad recesses 912 is formed on two opposite sides of the first electrode pad 91 and extends toward the interior of the first electrode pad 91.

The second electrode pad 92 includes a top view area smaller than the top view area of the second extension electrode 72. As shown in FIG. 1, the shape of the second electrode pad recess 922 may not necessarily correspond to the shape of the second extension electrode recess 722. As shown in FIGS. 2-6, the topography of the second electrode pad recess 922 may correspond to the topography of the second extension electrode recess 722. Even if the shape of the second electrode pad recess 922 does not correspond to the shape of the second extension electrode recess 722, as shown in FIG. 1, in order to expand the area of the second electrode pad 92, the distance D between one side of the one or the plurality of second electrode pad recesses 922 and one side of the second extension electrode recess 722 is less than the minimum distance dₘᵢₙ between the plurality of insulating reflective structure openings 400, and the plurality of second electrode pad recesses 922 is formed on the same side of the second electrode pad 92.

The first electrode pad 91 can be disposed on the first extension electrode 71 through the protective structure first opening 801, and the second electrode pad 92 can be disposed on the second extension electrode 72 through the protective structure second opening 802. The first bonding pad (not shown) can be disposed on the first electrode pad 91, and the second bonding pad (not shown) can be disposed on the second electrode pad 92. The first bonding pad and the second bonding pad can be formed of a conductive material (eg, Sn or AuSn). As shown in FIGS. 1-6, in the top view, the first electrode pad 91 can be adjacent to the first side 11 and the second electrode pad 92 can be adjacent to the second side 12.

The first electrode pad 91 and the second electrode pad 92 include metal materials, such as chromium (Cr), titanium (Ti), tungsten (W), gold (Au), aluminum (Al), indium (In), tin (Sn), nickel (Ni), platinum (Pt), silver (Ag) or the alloy of the above materials. The first electrode pad 91 and the second electrode pad 92 can be composed of a single layer or multiple layers. For example, the first electrode pad 91 or the second electrode pad 92 may include the Ti/Au layer, the Ti/Pt/Au layer, the Cr/Au layer, the Cr/Pt/Au layer, the Ni/Au layer, the Ni/Pt/Au layer, the Cr/Al/Cr/Ni/Au layer, or the Ag/NiTi/TiW/Pt layer. The first electrode pad 91 and the second electrode pad 92 can serve as the current path for the external power supply to the first semiconductor layer 21 and the second semiconductor layer 23. In an embodiment, each of the first electrode pad 91 and the second electrode pad 92 includes a thickness between 0.5 μm and 5 μm.

In an embodiment, the insulating layer 42, the insulating structure 60 and the protective structure 80 are disposed on the semiconductor stack 20 and serve as the interlayer insulating films for protection and anti-static of the optoelectronic devices 1-6. In an embodiment, as the insulating film, the insulating layer 42, the insulating structure 60 and the protective structure 80 can be a single-layer structure, including metal oxide or metal nitride. For example, an oxide or nitride film selected from the group consisting of silicon (Si), titanium (Ti) zirconium (Zr), niobium (Nb), tantalum (Ta), and aluminum (Al). In another embodiment, the insulating layer 42, the insulating structure 60 and the protective structure 80 include two or more materials with different refractive indexes that are alternately stacked to form a Distributed Bragg Reflector (DBR) structure to selectively reflect the specific wavelength. For example, a high reflectivity reflective structure can be formed by stacking two or three material insulating layers such as SiO₂, TiO₂, Nb₂O₅ or Al₂O₃. For example, when sub-layers such as SiO₂/TiO₂ or SiO₂/Nb₂O₅ are stacked to form a Distributed Bragg Reflector (DBR) structure, the one or an integer multiple of optical thickness of each sub-layer of the Distributed Bragg Reflector structure is designed to be a quarter of the wavelength of the light emitted from the active layer 22. The optical thickness of each sub-layer of the Distributed Bragg Reflector (DBR) structure can have a deviation of +30% based on one or an integer multiple of 2/4. Since the change in the optical thickness of each sub-layer of the Distributed Bragg Reflector structure will affect the reflectivity, the physical thickness of each sub-layer of the insulation layer 42, the insulating structure 60 and the protective structure 80 obtained based on the optical thickness of the Distributed Bragg Reflector structure can be formed by using E-beam evaporation to stably control the thickness of each sub-layer in the insulating layer 42, the insulating structure 60 and the protective structure 80.

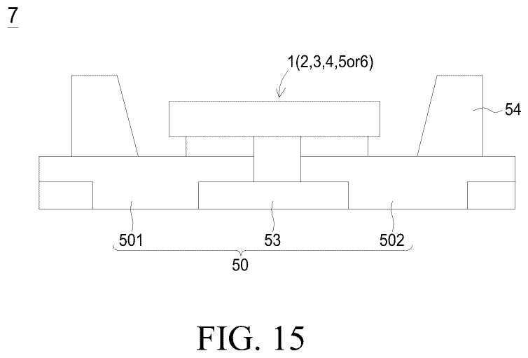

FIG. 15 illustrates a schematic diagram of the light-emitting apparatus 7 in accordance with an embodiment of the present application. One of the optoelectronic devices 1-6 in the aforementioned embodiments is mounted on the first pad 501 and the second pad 502 of the packaging substrate 50 in the form of a flip chip. The first pad 501 and the second pad 502 are electrically insulated by an insulating portion 53 including the insulating material. In the flip-chip mounting, the side of the growth substrate opposite to the electrode pad formation surface is set upward as the main light extraction surface. For example, the light-emitting surface 10t of the substrate 10 of the optoelectronic devices 1-6 is provided as the main light extraction surface of the optoelectronic devices 1-6. In order to increase the light extraction efficiency of the light-emitting apparatus 7, a reflective structure 54 can be provided around the optoelectronic devices 1-6.

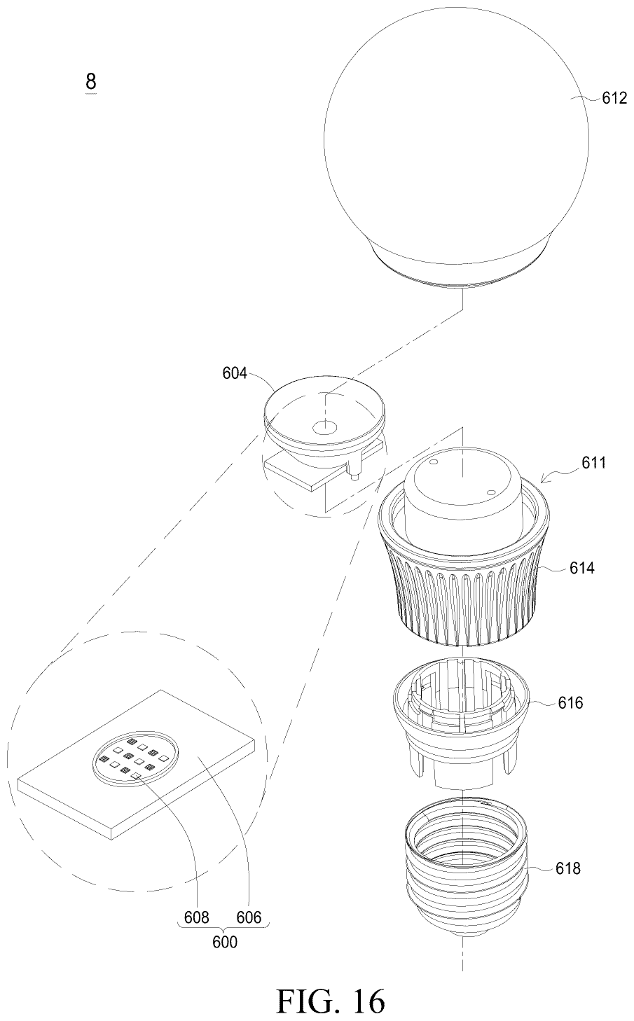

FIG. 16 illustrates a schematic diagram of the light-emitting apparatus 8 in accordance with an embodiment of the present application. The light-emitting apparatus 8 can be a bulb including an envelope 612, a lens 604, a light-emitting module 600, a base 611, a heat sink 614, a connector 616, and an electrical connecting element 618. The light-emitting module 600 includes a submount 606 and a plurality of light-emitting elements 608 on the submount 606, wherein the plurality of light-emitting elements 608 can be the optoelectronic devices 1-6 or the light-emitting apparatus 7 described in above embodiments.

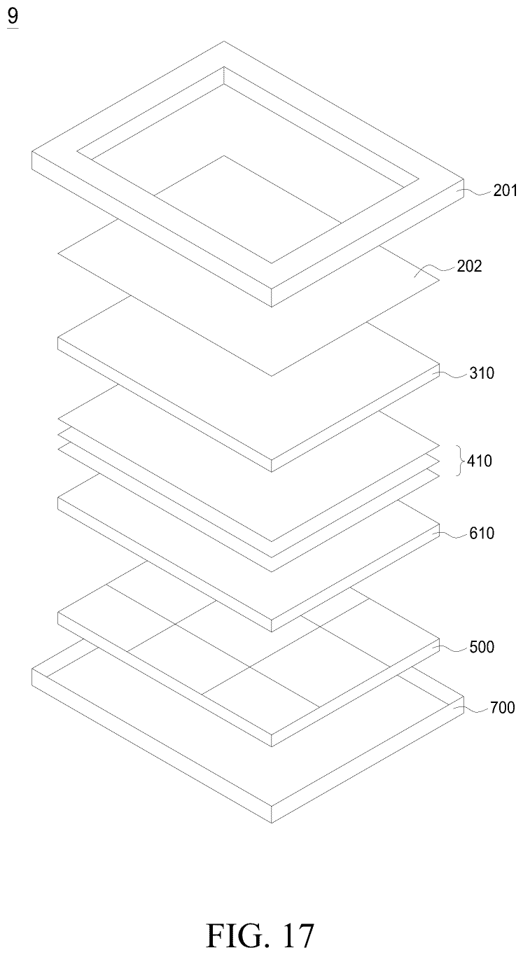

FIG. 17 illustrates a schematic diagram of the backlight module 9 in accordance with an embodiment of the present application. The backlight module 9 includes a first frame 201, a liquid crystal display panel 202, a brightness enhancement film 310, an optical module 430, a light-emitting module component 500, and a second frame 700. The light-emitting module component 500 includes one of the plurality of the optoelectronic devices 1-6 or the light-emitting apparatus 7 in the aforementioned embodiments, and is provided in the light-emitting module component 500 in an edge type or direct type. In an embodiment, the backlight module 4 further includes a wavelength conversion structure 610 disposed on the light-emitting module component 500.

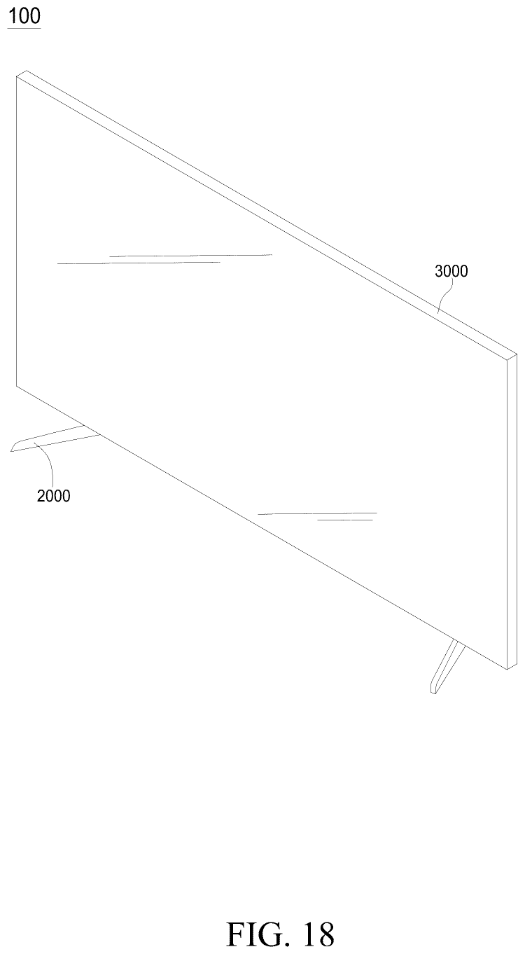

FIG. 18 illustrates a schematic diagram of a display 100 in accordance with an embodiment of the present application. The display 100 includes an LED light-emitting panel 3000 and a current source (not shown). The bracket 2000 is used to support the LED light-emitting panel 3000. The LED light-emitting panel 3000 includes any one of the plurality of the optoelectronic devices 1-6, the light-emitting apparatus 7 or the backlight module 9 in the aforementioned embodiments. In an embodiment, the LED light-emitting panel 3000 includes a plurality of pixel units. Each pixel unit includes one of the plurality of optoelectronic devices 1-6 or the light-emitting apparatus 7 in the aforementioned embodiments to emit different colors. For example, each pixel unit includes three of the optoelectronic devices 1-6 or light-emitting apparatuses 7 that respectively emit red light, green light, and blue light.

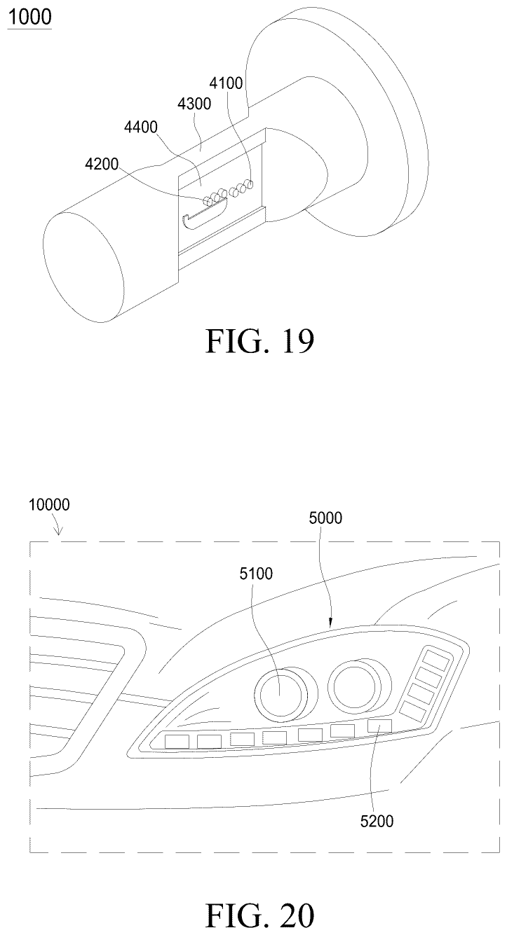

FIG. 19 illustrates a schematic diagram of a light-emitting apparatus 1000 in accordance with an embodiment of the present application. In an embodiment, the light-emitting apparatus 1000 is an LED bulb for automobiles, which can be plugged and fixed into the mounting through hole on the rear shell of the automobile headlight assembly. The light-emitting apparatus 1000 includes a first LED chip 4100 for low beam lighting or a second LED chip 4200 for high beam lighting, a long columnar lamp post 4300, a driving power circuit board 4400, heat dissipation fins for heat dissipation (not shown), a fan (not shown) for heat dissipation, a fan cover (not shown) for protecting the fan, and a power cord (not shown) for the electrical connection with the vehicle battery, and a plug (not shown) arranged on the end of the power supply. The first LED chip 4100 or the second LED chip 4200 in the light-emitting apparatus 1000 may include any one or more of the aforementioned optoelectronic devices 1-6 or the light-emitting apparatus 7.

FIG. 20 illustrates a schematic diagram of a light-emitting apparatus 10000 in accordance with an embodiment of the present application. In an embodiment, the light-emitting apparatus 10000 can be a vehicle lighting lamp 5000, which can be applied in the daytime running lights, the headlights, the tail lights, or the direction lights. The main lighting lamp 5100 can be a main lighting lamp in the vehicle lighting lamp 5000. For example, when the vehicle lighting lamp 5000 is used as a headlight, the main lighting lamp 5100 may have a headlight that illuminates the front of the vehicle. The combination lighting lamp 5200 can have at least two functions. For example, when the vehicle lighting lamp is used as a headlight, the combination lighting lamp 5200 can perform the functions of a daytime running light (DRL) and a direction indicator lamp. The main lighting lamp 5100 or the combination lighting lamp 5200 may include any one or more of the aforementioned optoelectronic devices 1-6 or the light-emitting apparatus 7.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. An optoelectronic device, including:
a semiconductor stack including a first semiconductor layer, an active layer, and a second semiconductor layer;
a contact electrode formed on the second semiconductor layer;
an insulating reflective structure covering the contact electrode, and including a plurality of insulating reflective structure openings to expose the contact electrode;
a metal reflective structure covering the plurality of insulating reflective structure openings, and electrically connected to the contact electrode;
an insulating structure including one or more first insulating structure openings to expose the first semiconductor layer and one or more second insulating structure openings to expose the metal reflective structure;
a first extension electrode covering the semiconductor stack and the one or more first insulating structure openings to electrically connect to the first semiconductor layer; and
a second extension electrode covering the semiconductor stack and the one or more second insulating structure openings to electrically connect to the metal reflective structure, wherein in a top view of the optoelectronic device, the one or more second insulating structure openings is formed at a position within a polygon constituted by the plurality of insulating reflective structure openings.

2. The optoelectronic device according to claim 1, wherein the contact electrode includes indium tin oxide (ITO), zinc doped indium tin oxide (ZITO), zinc indium oxide (ZIO), gallium indium oxide (GIO), zinc tin oxide (ZTO), fluorine doped tin oxide (FTO)), aluminum doped zinc oxide (AZO), gallium doped zinc oxide (GZO), or zinc magnesium oxide (Zn₍₁₋ₓ₎MgₓO, 0≤x≤1).

3. The optoelectronic device according to claim 2, further including a connecting layer covering the plurality of insulating reflective structure openings, wherein the connecting layer includes titanium (Ti), aluminum oxide (Al₂O₃), indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1).

4. The optoelectronic device according to claim 3, wherein the connecting layer includes a thickness smaller than that of the contact electrode.

5. The optoelectronic device according to claim 3, wherein the contact electrode and the connecting layer include a same material.

6. The optoelectronic device according to claim 3, wherein the contact electrode and the connecting layer include different materials.

7. The optoelectronic device according to claim 1, wherein the polygon includes a triangle, a rectangle, a pentagon, or a hexagon.

8. The optoelectronic device according to claim 7, wherein the position is located on an incenter, a circumcenter, an orthocenter, or a centroid of the triangle.

9. The optoelectronic device according to claim 7, wherein the triangle is an equilateral triangle.

10. The optoelectronic device according to claim 1, wherein the one or more second insulating structure openings includes a width not greater than a width of each of the plurality of insulating reflective structure openings.

11. The optoelectronic device according to claim 1, wherein the one or more second insulating structure openings each includes a width greater than that of each of the plurality of the insulating reflective structure openings.

12. The optoelectronic device according to claim 1, further including a protective structure formed on the first extension electrode and the second extension electrode, wherein the protective structure includes a protective structure first opening formed on the first extension electrode and a protective structure second opening formed on the second extension electrode.

13. The optoelectronic device according to claim 12, further including a first electrode pad formed on the protective structure first opening and a second electrode pad formed on the protective structure second opening.

14. The optoelectronic device according to claim 13, wherein the one or more second insulating structure openings are located in an area outside a projected area of the second electrode pad, and is covered by the second extension electrode.

15. The optoelectronic device according to claim 13, wherein the one or more second insulating structure openings are arranged along the second electrode pad.

16. The optoelectronic device according to claim 13, wherein the one or more second insulating structure openings are formed on two opposite sides of the second electrode pad.

17. The optoelectronic device according to claim 13, wherein the plurality of first insulating structure openings is located in an area outside a projected area of the first electrode pad and is covered by the first extension electrode.

18. The optoelectronic device according to claim 13, wherein the plurality of insulating reflective structure openings includes a first group of openings formed under the first electrode pad, and a second group of openings formed under the second electrode pad, wherein any two adjacent openings of the first group of openings are separated by a first minimum distance, any two adjacent openings of the second group of the openings are separated by a second minimum distance, the first minimum distance is greater than the second minimum distance.

19. The optoelectronic device according to claim 18, further includes one or more through holes penetrating through the active layer and the second semiconductor layer, and exposing the first semiconductor layer, wherein the plurality of insulating reflective structure openings surrounds the one or more through holes with a minimum distance, and the minimum distance is greater than the first minimum distance or the second minimum distance.

20. The optoelectronic device according to claim 19, wherein the one or more through holes include a first group of through holes surrounded by the first electrode pad, a second group of through holes surrounded by the second electrode pad, or both.
